(19) United States
(12) Patent Application Publication
(10) Pub. No.: US 2019/0287825 A1
(43) Pub. Date: Sep. 19, 2019

(54) PLASMA PROCESSING METHOD AND PLASMA PROCESSING APPARATUS

(71) Applicant: HITACHI HIGH-TECHNOLOGIES CORPORATION, Tokyo (JP)

(72) Inventor: Keiichi TANAKA, Tokyo (JP)

(21) Appl. No.: 16/353,513

(22) Filed: Mar. 14, 2019

(30) Foreign Application Priority Data
Mar. 16, 2018 (JP) 2018-049182

(51) Int. Cl. H01L 21/67; H01J 37/32; H01L 21/3065; H01L 21/683; H01L 21/311; H01L 21/3213

(52) U.S. Cl. CPC H01L 21/67069; H01J 2237/24585; H01L 21/67017; H01J 37/32192; H01L 21/67115; H01J 37/32449; H01L 21/67248; H01L 21/3065; H01J 37/32935; H01L 21/6833; H01L 21/31116; H01L 21/32137; H01J 2237/002; H01J 2237/3341; H01J 37/32724

(57) ABSTRACT

According to one embodiment, a plasma processing apparatus includes: a vacuum container; a sample stage on which a sample is mounted in an interior of the vacuum container; an exhaust unit which exhausts the interior of the vacuum container; a gas supply unit which supplies a processing gas to the interior of the vacuum container; a high frequency power application unit which applies a high frequency power to the interior of the vacuum container; an irradiation unit which irradiates the sample mounted on the sample stage with infrared light from an outside of the vacuum container; and a control unit which controls the exhaust unit, the gas supply unit, the high frequency power application unit, the irradiation unit, and a temperature measurement unit which measures a temperature of a surface of the sample stage on which the sample is mounted. The control unit controls an intensity of the infrared light with which the irradiation unit irradiates the sample based on the temperature measured by the temperature measurement unit when the irradiation unit irradiates the sample mounted on the sample stage with the infrared light.

### BACKGROUND OF THE INVENTION

### 1. Field of the Invention

The present invention relates to a plasma processing method and a plasma processing apparatus, and in particular, to a plasma processing method and a plasma processing apparatus suitable for etching a sample with atomic layer level accuracy by using a plasma.

### 2. Description of Related Art

In order to meet the needs of improvement in circuit performance and increase in memory capacity, semiconductor integrated circuits are being miniaturized and three-dimensionalized. With further miniaturization of integrated circuits, it is required to form a circuit pattern having a higher aspect ratio. In order to stably form the circuit pattern having a high aspect ratio, a dry cleaning/removing technique is required for a semiconductor manufacturing process, instead of a wet cleaning/removing technique in the related art.

As one of the dry cleaning/removing techniques, development of a processing technique for forming a pattern with an atomic layer level controllability has been proceeding as described in, for example, WO 2013/168509 A1 (PTL 1). A technique called atomic level etching (ALE) has been developed as a processing technique for forming a pattern with an atomic layer level controllability. However, WO 2013/168509 A1 discloses a technique of etching an object to be processed at the atomic layer level by supplying a microwave to generate a plasma at a low electron temperature of an inert gas by a rare gas (Ar gas) in a state where an etchant gas is adsorbed to the object to be processed and by separating constituent atoms of the substrate to be processed coupled with the etchant gas by heat generated by activation of the rare gas from the object to be processed without breaking bonds.

In addition, JP-A-2016-178257 (PTL 2) discloses a plasma processing apparatus as an adsorption/desorption type etching apparatus using irradiation with infrared light, the plasma processing apparatus including: a vacuum container which can be depressurized; a radical source which is disposed in an interior of a processing chamber in an interior of the vacuum container and generates active species; a wafer stage which is disposed below the radical source in the processing chamber and has a wafer mounted on an upper surface of the wafer stage; a lamp unit which is disposed between the radical source and the wafer stage in the processing chamber for heating the wafer; a flow passage which is disposed at an outer periphery side and a center portion of the lamp unit in the processing chamber and allows the active species to flow downward, and a control unit which adjusts supply of gases from a plurality of gas supply units for supplying a processing gas to the central portion and the outer periphery side portion of the radical source.

On the other hand, it is important to control the temperature of the object (wafer) in order to etch the object to be processed at the atomic layer level by this ALE method. JP-A-2000-208524 (PTL 3) discloses a method of rapidly obtaining the temperature distribution during the heat treatment of the semiconductor wafer for the temperature monitoring without opening the interior of the processing container to the atmosphere.

In order to control the etching at the atomic layer level, it is necessary to minimize the damage to the surface of the sample by plasma and increase the control accuracy of the etching amount. As a method corresponding to this, as described in PTLs 1 and 2, there is a method of chemically adsorbing the etchant gas on the surface of the substrate to be processed and applying thermal energy to the surface layer to detach the surface layer of the substrate to be processed.

However, according to the method described in PTL 1, since the surface of substrate to be processed is heated by a microwave-activated rare gas at a low electron temperature, there is a problem in that the heating time of the substrate to be processed is shortened and thus, the throughput of processing cannot be increased.

On the other hand, in the plasma processing apparatus described in PTL 2, since a lamp emitting infrared light is used for heating the surface of the substrate to be processed, the wafer which is the substrate to be processed can be heated in a relatively short time by controlling the voltage applied to the lamp. In a case of heating the wafer, since relatively high energy charged particles and the like are not incident on the surface of the wafer, it is possible to detach the surface layer by adsorbing the etchant gas without damaging the surface of the wafer.

However, various films are formed on the surface of the wafer, which is the substrate to be processed, according to the processes that have been performed so far, and in some cases, even if the same processes are performed, the reflectance of the surface and the heat capacity are slightly changed for wafer to wafer. As a result, there is a possibility that the reflectance of the wafer surface to the infrared light irradiated from the lamp or the thermal absorptivity of the wafer differs from wafer to wafer. In the plasma processing apparatus described in PTL 2, these points are not taken into consideration, and in a case where the reflectance of the surface or the thermal absorptivity differs from wafer to wafer, it is difficult to process each wafer at an optimum temperature.

### SUMMARY OF THE INVENTION

The present invention is to provide a plasma processing method and a plasma processing apparatus capable of improving an efficiency of processing of a wafer which is a substrate to be processed and increasing a throughput of processing.

According to an aspect of the present invention, a plasma processing apparatus includes: a vacuum container; a sample stage on which a sample is mounted in an interior of the vacuum container; an exhaust unit which exhausts the interior of the vacuum container; a gas supply unit which supplies a processing gas to the interior of the vacuum container; a high frequency power application unit which applies a high frequency power to the interior of the vacuum container; an irradiation unit which irradiates the sample mounted on the sample stage with infrared light from an outside of the vacuum container; and a control unit which controls the exhaust unit, the gas supply unit, the high frequency power application unit, the irradiation unit, and a temperature measurement unit which measures a temperature of a surface of the sample stage on which the sample is mounted, wherein the control unit controls an intensity of the infrared light with which the irradiation unit irradiates the sample based on the temperature measured by the temperature measurement unit when the irradiation unit irradiates the sample mounted on the sample stage with the infrared light.

According to another aspect of the present invention, a plasma processing method includes: generating a plasma in an interior of a plasma generation chamber by applying a high frequency power from a high frequency power application unit to the interior of the plasma generation chamber in a state where a processing gas is supplied from a gas supply unit; attaching an excitation gas by the processing gas flowing into a processing chamber connected to the plasma generation chamber among the processing gas excited by plasma generated in the interior of the plasma generation chamber to a surface of a sample mounted on a sample stage in the interior of the processing chamber and cooled to a predetermined temperature; and performing a removal process of removing the surface of the sample one by one by repeatedly irradiating the sample to which the excitation gas is attached with infrared light from an irradiation unit to the sample to heat the sample to remove one layer of the surface of the sample, wherein the irradiating the sample to which the excitation gas is attached with the infrared light from the irradiation unit is performed based on a temperature measured by a temperature measurement unit which measures a temperature of a surface on which the sample of the sample stage is mounted while irradiating the sample and controlling an intensity of the infrared light with which the irradiation unit irradiates the sample.

According to the present invention, it is possible to improve a processing efficiency of a wafer which is a substrate to be processed and to increase a throughput of processing.

In addition, according to the present invention, even for a wafer of which temperature rising rate (volume resistivity) is unknown, it is possible to maintain the minimum temperature required for the process for a predetermined period of time without lowering the throughput of the processing, and it is possible to improve the yield of the processing.

### BRIEF DESCRIPTION OF THE DRAWINGS

FIG. 1 is a block diagram illustrating a schematic configuration of a plasma processing apparatus according to the embodiment of the present invention;

FIG. 2 is a cross-sectional view of a sample stage of a plasma processing apparatus according to the embodiment of the present invention;

FIGS. 3A to 3D are diagrams illustrating the operation in a one cycle step of removing one layer on the surface of the sample by the plasma processing apparatus according to the embodiment of the present invention, wherein FIG. 3A is a timing chart of discharging, FIG. 3B is a timing chart of lamp heating, FIG. 3C is a timing chart of supply of the cooling gas, and FIG. 3D is a graph illustrating a change in temperature of the wafer;

FIG. 4 is a perspective view of a wafer explaining attachment positions of temperature sensors on the surface of the wafer in a case where the temperature of the surface of the sample in the plasma processing apparatus according to the embodiment of the present invention is measured at a plurality of points;

FIG. 5 illustrates a temporal change of an average value of temperatures detected by a plurality of temperature sensors attached to a wafer at each time at the time of supplying a predetermined power to allow the lamp to emit light and to heat the wafer for the wafer having the largest volume resistivity among the wafers as the processing objects and a temperature detected by a temperature sensor installed in an interior of the sample stage in the plasma processing apparatus according to the embodiment of the present invention;

FIG. 6 illustrates lines connecting the temperature rising rate of the average temperature of the temperature detected by the plurality of temperature sensors attached to the surface of the wafer as illustrated in FIG. 4 at the time of setting the power applied to the lamp and the pressure of the cooling gas supplied between the wafer and the sample stage to certain values for the wafer having the largest volume resistivity and the wafer having the smallest volume resistivity from the data stored in the database illustrated in FIG. 5 and the temperature rising rate detected by a temperature sensor installed in an interior of the sample stage;

FIG. 7A is a timing chart of lamp heating in the plasma processing apparatus according to the embodiment of the present invention, and FIG. 7B is a graph illustrating a change in wafer temperature corresponding to lamp heating in FIG. 7A;

FIG. 8A is a timing chart of lamp heating in the plasma processing apparatus according to the embodiment of the present invention in a case of using a wafer having a large volume resistivity as compared with the case of FIG. 7A, and FIG. 8B is a graph illustrating a change in wafer temperature corresponding to the lamp heating in FIG. 8A;

FIG. 9 is a timing chart of a processing cycle for explaining a method of checking the relationship between the temperature detected by the temperature sensor in advance and the temperature of the surface of the wafer for wafer as the processing object at the first cycle of the repeatedly executed processing cycle in the plasma processing apparatus according to the embodiment of the present invention;

FIG. 10 is a timing chart of a processing cycle for explaining a method of identifying the temperature rising rate of the wafer as the processing object from the temperature detected by the temperature sensor by heating the wafer in a fixed sequence before starting the repeatedly executed processing cycle in the plasma processing apparatus according to the embodiment of the present invention; and

FIG. 11 is a block diagram illustrating a schematic configuration of a control unit of the plasma processing apparatus according to the embodiment of the present invention.

### DESCRIPTION OF EMBODIMENTS

The present invention relates to a plasma processing apparatus in which a sample is heated intermittently by radiation from a lamp a plurality of times to process a film on a surface of the sample, wherein a resistivity of the sample is detected from information on a change in temperature of the sample involved with the elapse of the time obtained during a first heating cycle or before the first heating cycle among a plurality of heating cycles for processing the sample and the data on the temporal change of the temperature of the sample having the equivalent configuration previously acquired, and a change of the temperature of the sample corresponding to the detected resistivity is estimated in a subsequent heating cycle to perform specific lamp control.

Hereinafter, embodiments of the present invention will be described in detail with reference to the drawings. In all the drawings for explaining the embodiment, components having the same function are denoted by the same reference numerals, and redundant description thereof will be omitted in principle.

### Embodiment

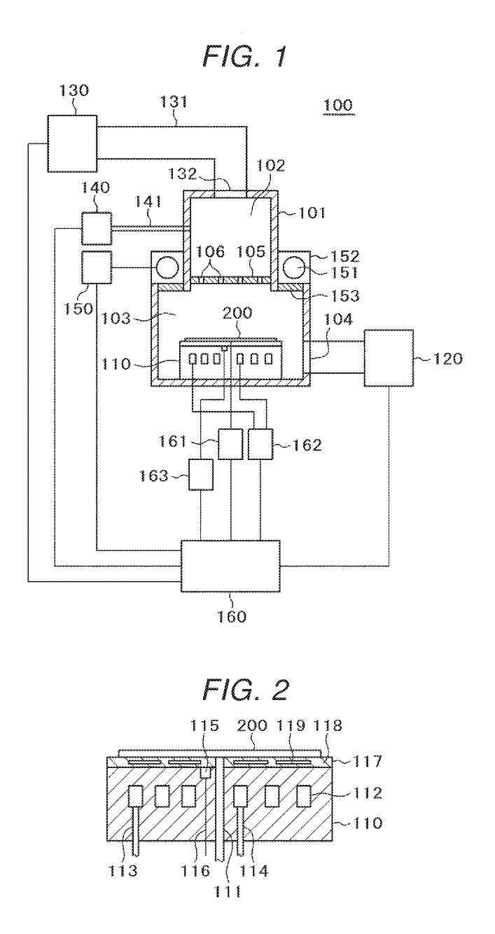

FIG. 1 illustrates a configuration of a plasma processing apparatus 100 according to an embodiment of the present invention. The plasma processing apparatus 100 according to the embodiment includes a vacuum container 101, a sample stage 110 which is disposed in an interior of the vacuum container 101, a vacuum exhaust device 120 which exhausts the interior of the vacuum container 101 to maintain vacuum, a high frequency power supply 130 which supplies a high frequency (microwave) power to the interior of the vacuum container 101, a gas supply source 140 which supplies a processing gas to the interior of the vacuum container, a lamp power supply 150 which supplies a power to a lamp 151 for heating a wafer 200 which is a substrate to be processed mounted on the sample stage 110, and a control unit 160 which controls the entire plasma processing apparatus 100.

The vacuum exhaust device 120 is connected to an opening 104 of the vacuum container 101 to exhaust the interior of the vacuum container 101 and maintain a predetermined pressure (degree of vacuum) of the interior of the vacuum container 101. The high frequency power (microwave power) generated by the high frequency power supply 130 passes through the interior of a hollow waveguide 131 and is supplied from an opening 132 to a plasma generation chamber 102 in an upper portion of the vacuum container 101. In addition, the processing gas is also supplied to the plasma generation chamber 102 from the gas supply source 140 through a gas introduction pipe 141.

The vacuum container 101 includes the plasma generation chamber 102 which generates plasma and a processing chamber 103 which is in a lower portion of the plasma generation chamber 102 and in which the sample stage 110 is installed. The wafer 200 which is a substrate to be processed is mounted on the upper surface of the sample stage 110. A plate 105 formed of quartz (SiO₂) is installed in the boundary between the plasma generation chamber 102 and the processing chamber 103. A large number of slits 106 are formed in the plate 105.

A large number of the slits 106 formed in the plate 105 are formed with such a size as to prevent the plasma generated in the plasma generation chamber 102 from flowing toward the side of the processing chamber 103. The processing gas excited by the plasma generated in the plasma generation chamber 102 flows out from the plasma generation chamber 102 to the processing chamber 103.

The lamp 151 is disposed outside the vacuum container 101 so as to surround the vacuum container 101, and the periphery thereof is covered with a protection plate 152. A window portion 153 made of quartz that transmits infrared rays generated by the lamp 151 is formed in the portion of the vacuum container 101 corresponding to the surface through which the wafer 200 mounted on the sample stage 110 in the interior of the processing chamber 103 is monitored from the lamp 151.

With such a configuration, the wafer 200 mounted on the sample stage 110 in the interior of the processing chamber 103 can be heated by the lamp 151 disposed outside the vacuum container 101. In addition, at this time, by adjusting the power applied from the lamp power supply 150 to the lamp 151, the temperature at which the wafer 200 is heated can be controlled.

The configuration of the sample stage 110 is illustrated in FIG. 2.

A gas supply pipe 111 for supplying a cooling gas to the back surface of the wafer 200 mounted on the sample stage 110 is buried in the interior of the sample stage 110. The gas supply pipe 111 is connected to a gas flow rate control unit 161 which controls the flow rate of the cooling gas outside the processing chamber 103, and the flow rate of cooling gas which is to be supplied to the back surface of the wafer 200 is adjusted.

In addition, a flow passage 112 through which a coolant for cooling the sample stage 110 flows is formed in the interior of the sample stage 110, and a supply pipe 113 for supplying the coolant to the flow passage 112 and a discharge pipe 114 for discharging the coolant are connected. The supply pipe 113 and the discharge pipe 114 are connected to a coolant temperature controller 162 outside the processing chamber 103, and a coolant of which temperature is adjusted is supplied to the flow passage 112 from the supply pipe 113.

Furthermore, a temperature sensor 115 for measuring the temperature of the surface on which the wafer 200 is mounted and a conductor line 116 for connecting the temperature sensor 115 and a sensor controller 163 are buried in the interior of the sample stage 110. As the temperature sensor 115, for example, a thermocouple type temperature sensor is used.

An electrostatic chuck 117 is formed on the upper surface of the sample stage 110. The electrostatic chuck 117 has a configuration in which a pair of electrodes (thin film electrodes) 119 are formed as thin films in an interior of a thin insulating film layer 118. By applying a power from a power supply (not illustrated) to the pair of thin film electrodes 119, the wafer 200 mounted on the upper surface of the insulating film layer 118 can be adsorbed to the upper surface of the insulating film layer 118 by an electrostatic force.

When the cooling gas is supplied from the gas supply pipe 111 to the space between the wafer 200 and the upper surface of the insulating film layer 118 in a state where the wafer 200 is adsorbed by the electrostatic force as described above, the supplied cooling gas flows through a minute space formed between the back surface of the wafer 200 and the upper surface of the insulating film layer 118, flows out to the interior of the processing chamber 103, and is exhausted by the vacuum exhaust device 120. The cooling gas flows through the minute space formed between the back surface of the wafer 200 and the upper surface of the insulating film layer 118, so that heat transfer is performed between the back surface of the wafer 200 and the insulating film layer 118. Herein, when the sample stage 110 is cooled by the coolant flowing through the flow passage 112, the heat of the wafer 200 flows to the side of the sample stage via the insulating film layer 118, and thus, the wafer 200 is cooled.

On the other hand, when the supply of the cooling gas from the gas supply pipe 111 to the space between the wafer 200 and the upper surface of the insulating film layer 118 is stopped in a state where the electrostatic adsorption of the wafer 200 by the electrostatic chuck 117 is stopped, heat transfer between the back surface of the wafer 200 and the insulating film layer 118 is not performed. When the wafer 200 is heated in this state, heat is accumulated in the wafer 200, and the temperature of the wafer 200 is increased.

The vacuum exhaust device 120, the high frequency power supply 130, the gas supply source 140, the lamp power supply 150, the gas flow rate control unit 161, the coolant temperature controller 162, and the sensor controller 163 are controlled by the control unit 160. In addition, the control unit 160 also controls a power supply (not illustrated) for the electrostatic chuck 117.

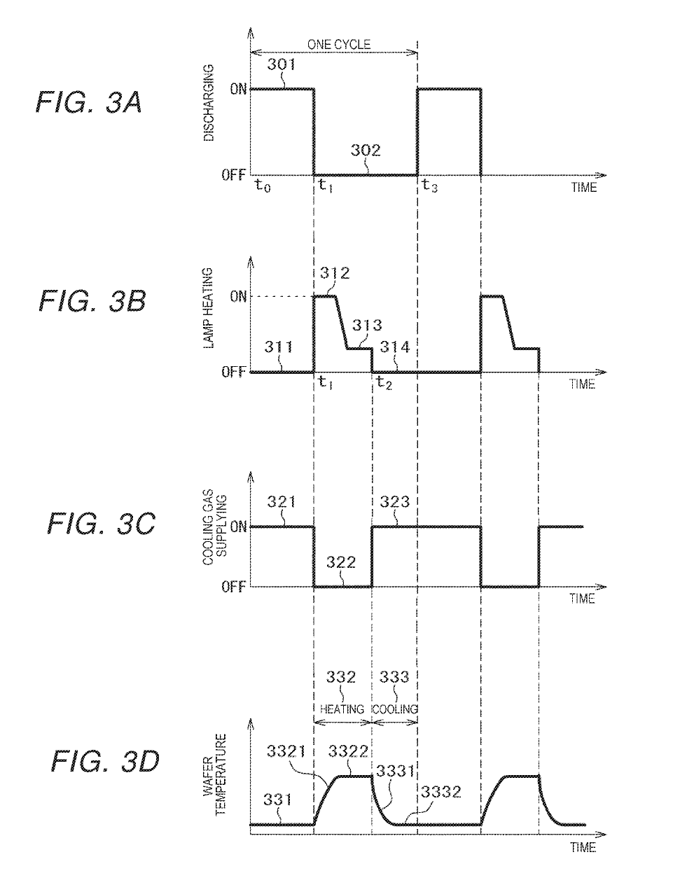

The process of etching the thin film formed on the surface of the wafer 200 at the atomic layer level by using such a structure will be described with reference to the time chart illustrated in FIGS. 3A to 3D. FIG. 3A illustrates a temporal change of the generation of plasma in the interior of the plasma generation chamber 102. FIG. 3B illustrates a temporal change of the lamp heating for supplying the power from the lamp power supply 150 to the lamp 151 to allow the lamp 151 to emit light to heat the wafer 200. FIG. 3C illustrates the timing of supplying (ON) and stopping (OFF) of the cooling gas which is to be supplied between the wafer 200 held on the sample stage 110 and the sample stage 110. FIG. 3D illustrates a temporal change of the temperature detected by the temperature sensor 115.

First, the wafer 200 is mounted on the upper surface of the sample stage 110 by using a transport unit (not illustrate), and the electrostatic chuck 117 is operated by a power supply (not illustrated), so that the wafer 200 is held onto the upper surface of the sample stage 110.

In this state, the vacuum exhaust device 120 is operated to exhaust the interior of the vacuum container 101, and at the step where the interior of the vacuum container 101 reaches a predetermined pressure (degree of vacuum), the gas supply source 140 is operated to supply the processing gas the gas introduction pipe 141 to the interior of the plasma generation chamber 102. By adjusting any one or both of the flow rate of the processing gas supplied to the interior of the plasma generation chamber 102 from the gas introduction pipe 141 and the exhaust amount of the vacuum exhaust device 120, the pressure of the interior of the vacuum container 101 is maintained to a preset pressure (degree of vacuum).

Herein, a silicon-based thin film is formed on the surface of the wafer 200, and in a case where this silicon-based thin film is etched, for example, NF3, NH 3, or CF-based gas is used as the processing gas supplied from the gas supply source 140 to the interior of the plasma generation chamber 102.

In this manner, in a state where the pressure of the interior of the vacuum container 101 is maintained to be a preset pressure (degree of vacuum), the high frequency power (microwave power) generated by the high frequency power supply 130 is supplied through the interior of the waveguide 131 from the opening 132 to the plasma generation chamber 102.

In the interior of the plasma generation chamber 102 to which the high frequency power (microwave power) is supplied, the processing gas supplied from the gas introduction pipe 141 is excited and the discharging is started, so that the plasma is generated (discharging ON: state 301 in FIG. 3A). Herein, the width of the slit 106 formed in the plate 105 is set so as to be smaller than the size of the sum of the widths of the sheath regions originally formed in the portions of the walls on both sides constituting the slit 106 by the plasma generated in the interior of the plasma generation chamber 102.

Accordingly, the plasma generated in the interior of the plasma generation chamber 102 tries to flow toward the side of the processing chamber 103 through the slit 106 formed in the plate 105, but the plasma gas cannot pass through the sheath region formed in the portions of the walls on both sides constituting the slit 106 but remains in the interior of the plasma generation chamber 102.

On the other hand, in a portion of the processing gas supplied to the interior of the plasma generation chamber 102, there exists a so-called excitation gas (radical) that is excited by the plasmatized gas but is not plasmatized. Since this excitation gas has no polarity, the excitation gas can pass through the sheath region formed in the portion of the slit 106 of the plate 105, and thus, the excitation gas is supplied to the side of the processing chamber 103.

Herein, the slits 106 formed in the plate 105 are disposed at a plurality of locations on the plate 105 such that the excitation gas (radical) passing through the slits 106 is uniformly diffused on the surface of the wafer 200 held on the upper surface of the sample stage 110.

At this time, the wafer 200 is adsorbed by the electrostatic chuck 117, the cooling gas is supplied from the gas supply pipe 111 between the wafer 200 and the surface of the electrostatic chuck 117 (ON: state 321 in FIG. 3C), and the temperature of the wafer 200 is set and maintained at a temperature (for example, 20° C. or less) suitable for forming a reaction layer by allowing the excitation gas adsorbed to the surface of the wafer 200 to react with the surface layer of the wafer 200 and preventing the reaction from further proceeding as indicated by the temperature 311 in FIG. 3D.

In this state, a portion of the excitation gas supplied to the side of the processing chamber 103 is adsorbed to the surface of the wafer 200 held on the upper surface of the sample stage 110, and thus, a reaction layer with the surface layer of the wafer 200 is formed.

After the excitation gas is continuously supplied to the side of the processing chamber 103 for a certain period of time (between a time t₀ in FIGS. 3A to 3D and a time t₁ in the discharging ON 301) to form the reaction layer on the entire surface of the silicon based thin film formed on the surface of the wafer 200, the supply of the high frequency power from the high frequency power supply 130 to the plasma generation chamber 102 is interrupted to stop the generation of the plasma in the interior of the plasma generation chamber 102 (discharging OFF: 302). Accordingly, the supply of the excitation gas from the plasma generation chamber 102 to the processing chamber 103 is stopped.

In this state, the supply of the cooling gas from the gas supply pipe 111 is stopped (cooling gas supply OFF: state 322 in FIG. 3A) to stop the cooling of the wafer 200. In addition, the operation of the electrostatic chuck 117 by a power supply (not illustrated) is stopped to release the holding of wafer 200 on the upper surface of the sample stage 110 by an electrostatic force.

On the other hand, the power is supplied from the lamp power supply 150 to the lamp 151 (lamp heating ON: state 312 in FIG. 3B) to allow the lamp 151 to emit light. The emitting lamp 151 emits the infrared light, and the wafer 200 mounted on the sample stage 110 is heated by the infrared light transmitted through the quartz window portion 153, so that the temperature of the wafer 200 is increased (wafer temperature: 3321 in FIG. 3D).

When the state 312 of the lamp heating ON is maintained and the temperature of the wafer 200 reaches the predetermined temperature, the power supplied from the lamp power supply 150 to the lamp 151 is switched to be reduced, and thus, the lamp heating is changed to the state 313 to suppress the increasing of the temperature of the wafer 200, so that the temperature of the wafer 200 is controlled so as to be maintained within a predetermined temperature range such as the temperature 3322.

In this manner, when the wafer 200 heated by the infrared light emitted from the lamp 151 is maintained within a predetermined temperature range for a certain period of time (temperature: state 3322 in FIG. 3D), the reaction product constituting the reaction layer formed on the surface of the wafer 200 is detached from the surface of the wafer 200. As a result, the uppermost surface layer of the wafer 200 is removed by one layer.

After the wafer 200 is heated by the lamp 151 for a predetermined period of time (the period of time 332 from the start of the lamp heating ON 312 at the time t₁ in FIG. 3B to the end of the lamp heating ON 313 at a time t₂), the supply of the power from the lamp power supply 150 to the lamp 151 is stopped, and the heating by the lamp 151 is ended (lamp heating OFF: 314 in FIG. 3B).

In this state, the power is applied from a power supply (not illustrated) to the pair of electrodes 119 of the electrostatic chuck 117, so that the wafer 200 is adsorbed to the electrostatic chuck 117, and the supply of the cooling gas from the gas supply pipe 111 is started (cooling gas supply ON: state 323 in FIG. 3C), so that the cooling gas is supplied between the wafer 200 and the sample stage 110. Due to this supplied cooling gas, the heat exchange is performed between the sample stage 110 cooled by the coolant flowing through the flow passage 112 and the wafer 200, and as indicated by the curve of the wafer temperature 3331 in FIG. 3D, the cooling is performed until the wafer 200 Is cooled down to a temperature suitable for forming the reaction layer.

The wafer 200 is cooled for a certain period of time (cooling time: 333 in FIG. 3D), and one cycle is ended in a state (a time t₃ in FIGS. 3A to 3D) where the temperature of the wafer 200 is sufficiently cooled to a temperature (wafer temperature 3332 in FIG. 3D) suitable for allowing the excitation gas adsorbed to the surface of the wafer 200 to react with the surface layer of the wafer 200 to form a reaction layer.

According to the embodiment, for a period of time 332 of heating the wafer 200, the wafer 200 is maintained to be a temperature necessary for detaching the reaction product from the surface of the wafer 200 without heating the wafer 200 more than necessary, so that, at the time of cooling the wafer 200, the wafer 200 can be cooled down to a temperature suitable for forming the reaction layer by excitation gas adsorbed to the surface of the wafer 200 in a relatively short time. Accordingly, it is possible to shorten the cooling time 333 as compared with the case of not controlling the temperature of the wafer 200 at the time of heating, and thus, it is possible to shorten the time of one cycle and to increase the throughput of processing.

In this manner, by repeating, a predetermined number of times, the cycle starting from attaching the excitation gas generated by generating the plasma in the interior of the plasma generation chamber 102 to the surface of the wafer 200, allowing the lamp 151 to emit light to heat the wafer 200 and to detach the reaction product from the surface of the wafer 200, after that, cooling until the temperature of the wafer 200 reaches a temperature suitable for forming the reaction layer, a desired number of stacked layers of the thin film layers formed on the surface of the wafer 200 can be removed layer by layer.

The irradiation energy of the infrared ray (IR) lamp is denoted by E₀, the surface reflection energy of the wafer 200 is denoted by Er, the absorption energy to the wafer is denoted by Ea, and the transmission energy of the wafer is denoted by Et. In this case, the irradiation energy E₀ of the infrared ray (IR) lamp is expressed by the following equation.

E₀=Er+Ea+Et

In addition, the reflectance of the surface of the wafer with respect to the energy irradiated by the lamp 151 is expressed as Er/E₀, the absorptivity of the wafer is expressed as Ea/E₀, and the transmittance of the wafer is expressed as Et/E₀.

Herein, in the actual wafer 200, the volume resistivity varies depending on the type and content of the doped metal to the silicon as the base material, and variation occurs in the shape dimensions and state (reflectance of the surface, heat capacity, and the like) of the thin film pattern formed on the surface. Due to the electromagnetic wave irradiated from the infrared lamp, the absorptivity (or the reflectance of the surface and the transmittance of the wafer) of the wafer is changed depending on the volume resistivity and the heat capacity (film thickness) of the base material of the wafer or the thin film pattern, and thus, the temperature rise characteristics (particularly, the temperature rising rate) is changed. As a result, even if the heating of the wafer 200 by the lamp 151 is controlled as illustrated in FIG. 3B, the temperature of each wafer 200 to be processed is changed every time, so that it is difficult to reproduce the temperature as a rising curve like the wafer temperature 3321 illustrated in FIG. 3D and in a certain range as illustrated in the wafer temperature 3322.

In addition, when the volume resistivity of the base material of the wafer 200 is changed and, thus, variation occurs in the shape dimensions and state (reflectance of the surface, heat capacity, and the like) of the thin film pattern formed on the surface, it is also difficult to accurately estimate the temperature of the surface of the wafer 200 being heated by the lamp 151 from the temperature detected by the temperature sensor 115 provided in the interior of the sample stage 110.

Therefore, in the embodiment, among the wafers 200 as the processing object, the wafer having the largest volume resistivity (small absorptivity to the wafer and small temperature rising rate) and the wafer having the smallest volume resistivity (large absorptivity to the wafer and large temperature rising rate) are extracted, the heating characteristics by the lamp 151 are measured in advance for the wafers 200, and the temperature of the wafer 200 being processed is estimated by using the measurement result.

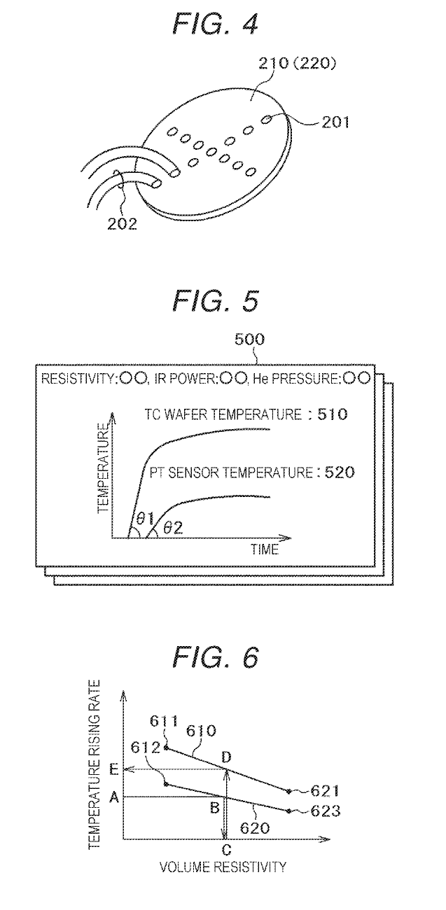

In order to measure the heating characteristics by the lamp 151, temperature sensors 202 such as thermocouples are attached to a plurality of points 201 as illustrated in FIG. 4 for the wafer 210 having the largest volume resistivity among the wafers 200 as the processing objects.

In place of the wafer 200 illustrated in FIG. 1, the wafer 210 to which the temperature sensor 202 is attached is mounted on the sample stage 110 of the plasma processing apparatus, and the interior of the processing chamber 103 is exhausted by the vacuum exhaust device 120, so that the interior of the vacuum container 101 is set to a predetermined pressure (degree of vacuum).

In a state where the interior of the vacuum container 101 is maintained at a predetermined pressure (degree of vacuum), the power is supplied from the lamp power supply 150 to the lamp 151, so that the lamp 151 is allowed to emit light. Among the infrared light beams emitted from the emitting lamp 151, by the infrared light beam which has passed through the window portion 153 made of quartz and has been incident on the processing chamber 103, the wafer 210 mounted on the sample stage 110 is heated.

The temperature of the wafer 210 in a state where the wafer is heated by the infrared light emitted from the lamp 151 is detected by a plurality of temperature sensors 202 attached to the wafer 210 and a temperature sensor 115 installed in the interior of the sample stage 110, and the relationship between the heating time by the lamp 151 and the change of each temperature detected by the temperature sensor 202 and the temperature sensor 115 is obtained.

Similarly, for the wafer 220 having the smallest volume resistivity among the wafers 200 as the processing objects, the relationship between the heating time by the lamp 151 and the change of each temperature detected by the temperature sensor 202 and the temperature sensor 115 is obtained.

An example of the result obtained by the measurement is illustrated in FIG. 5. The graph 500 illustrated in FIG. 5 illustrates the temporal change of an average value (TC wafer temperature: 501 in the graph of FIG. 5) of the temperatures detected by the plurality of temperature sensors 202 attached to the wafer 210 at respective times at the time of supplying a predetermined power (for example, 70% of the allowable maximum applied power of the lamp 151) from the lamp power supply 150 to the lamp 151 for the wafer 210 having the largest volume resistivity among the wafers 200 as the processing objects to allow the lamp 151 to emit light and heating the wafer 210 mounted on the sample stage 110 and the temperature (PT sensor temperature: 520 in the graph of FIG. 5) detected by the temperature sensor 115 installed in the interior of the sample stage 110.

The temperature rising rate (corresponding to the angle θ1 of the rising portion of the curve of the TC wafer temperature 510 in FIG. 5) detected by a plurality of the temperature sensors 202 attached to the surface of the wafer 210 and the temperature rising rate (corresponding to the angle θ2 of the rising portion of the curve of the PT sensor temperature 520 in FIG. 5) detected by the temperature sensor 115 are obtained from the graph obtained in this manner.

Such measurements is performed by variously changing the power (lamp power) applied from the lamp power supply 150 to the lamp 151 and the pressure of the cooling gas (helium: He) supplied between the wafer 210 and the sample stage 110 as parameters, and in each condition, a graph as illustrated in FIG. 5 is generated and stored as a database in the storage unit 1601 of the control unit 160.

In some cases, the average temperature expected to be detected by the plurality of temperature sensors 202 attached to the surface of the wafer 210 can be obtained from the temperature detected by the temperature sensor 115 installed in the interior of the sample stage 110 by using the database generated from the measurement in this manner.

This principle will be described with reference to FIG. 6. The straight line 610 illustrated in FIG. 6 is a line connecting the temperature rising rates obtained for the wafers 210 and 220 obtained by selecting the wafer 210 having the largest volume resistivity and the wafer 220 having the smallest volume resistivity from the data stored in the database illustrated in FIG. 5. The temperature rising rate is obtained from the temporal change of the temperature rising immediately after starting the heating of the wafer 210 by the lamp 151 when setting the power applied to the lamp 151 and the pressure of the cooling gas (helium: He) supplied between the wafer 210 (220) and the sample stage 110 to certain values.

That is, the straight line 610 is a line connecting the temperature rising rate 611 for the wafer 220 having the smallest volume resistivity which is the temperature rising rate obtained from the average temperature of the temperatures detected by the plurality of temperature sensors 202 attached to the surface of the wafer 210 (220) and the temperature rising rate 621 for the wafer 210 having the largest volume resistivity.

In addition, the straight line 620 is a line connecting the temperature rising rate 612 of the sample stage 110 detected by the temperature sensor 115 installed in the interior of the sample stage 110 at the same time when the temperature rising rate for the wafer 220 having the smallest volume resistivity is obtained by the plurality of temperature sensors 202 attached to the surface of the wafer 220 and the temperature rising rate 623 of the sample stage 110 detected by the temperature sensor 115 installed in the interior of the sample stage 110 at the same time when the temperature rising rate for the wafer 220 having the largest volume resistivity are obtained.

In actual process of the wafer 200, the rising temperature A is calculated from the temperature detected by the temperature sensor 115 installed in the interior of the sample stage 110 when the wafer 200 is heated by the lamp 151. Next, on the straight line 620 in the graph of FIG. 6, a position B corresponding to the temperature rising rate A is obtained. Next, the volume resistivity C corresponding to the position B on the straight line 620 is obtained, and the point D on the straight line 610 corresponding to this volume resistivity C is obtained. Finally, the temperature rising rate E corresponding to the point D on the straight line 610 is obtained, and from the elapsed time from the start of the heating of the wafer 200 by the obtained temperature rising rate E and the lamp 151 to the present time, the temperature of the surface of the wafer 200 at the present time is estimated.

In this manner, a characteristic wafer (in the embodiment, the wafer 210 having the largest volume resistivity and the wafer 220 having the smallest volume resistivity) extracted from the wafers 200 as the processing objects is extracted, and a database as explained in FIG. 5 is generated. Next, by obtaining the relationship between the temperature rising rate and the volume resistivity as illustrated in FIG. 6 and referring to the data stored in the database thereof, it is possible to estimate the temperature of the surface of the wafer 200 at the present time from the temperature detected by the temperature sensor 115 installed in the interior of the sample stage 110 while actually heating the wafer 200 being processed by the lamp 151.

Next, an example in which the embodiment is applied to an arbitrary wafer extracted among the wafers 200 as the processing objects will be described. First, the arbitrary extracted wafer 200 is heated by the lamp 151 in a state where the wafer is mounted on the sample stage, and the temperature rising rate is obtained from the change in the temperature detected by the temperature sensor 115 installed in the interior of the sample stage 110. Next, based on the temperature rising rate obtained from the temperature detected by the temperature sensor 115, the temperature rising rate of the surface of the wafer 200 is obtained by following the steps described with reference to FIG. 6.

In a case where the wafer 200 mounted on the sample stage is heated by the lamp 151, the power applied from the lamp power supply 150 to the lamp 151 at the start of the heating is constant (for example, 70% of the lamp rated power) every time. In a state where the wafer 200 is heated by the lamp 151, the temperature of the surface of the wafer is estimated from the temperature detected by the temperature sensor 115 based on the relationship between the temperature rising rate obtained from the temperature detected by the temperature sensor 115 stored in the database and the temperature rising rate of the surface of the wafer 200, as described above, and the heating by the lamp 151 is controlled.

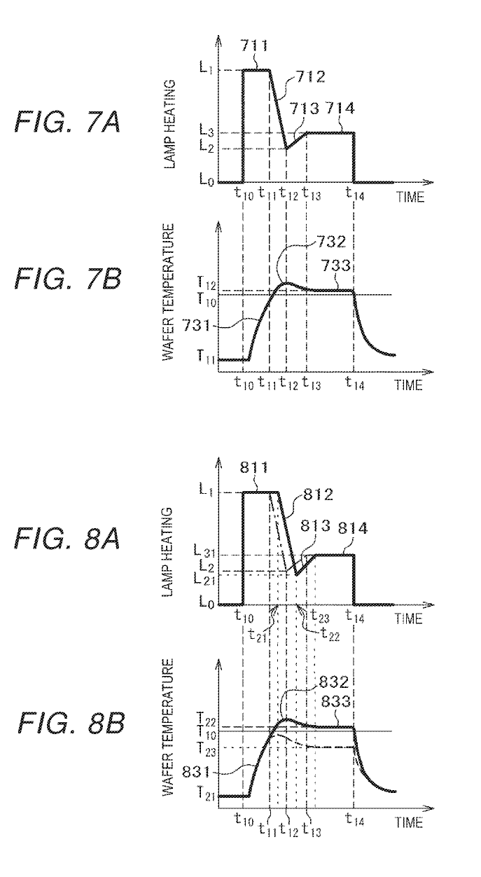

FIGS. 7A and 7B illustrate the period of time of performing the lamp heating corresponding to the heating 332 and the state at the time including before and after the period of time among the lamp heating described in FIG. 3B and the temporal change in the wafer temperature described in FIG. 3D. Based on the temperature of the surface of the wafer estimated from the temperature detected by the temperature sensor 115, the power (lamp power) applied from the lamp power supply 150 to the lamp 151 is controlled.

In the example illustrated in FIGS. 7A and 7B, with respect to the wafer of which the temperature rise characteristics of the surface are obtained by the above-described method, as illustrated in the time chart of FIG. 7A, by starting application of the power from the lamp power supply 150 to the lamp 151 at a time t₁₀, the lamp heating is set from a state L₀ to a state L₁ (heating: state 711), and the temperature 731 of the wafer 200 is increased as illustrated in the time chart of FIG. 7B. This state 711 of the heating is maintained, the lamp heating is switched from L₁ at a time point (a time t₁₁) when the wafer temperature 732 estimated from the temperature detected by the temperature sensor 115 reaches a preset target value T₁₀, and at a time t₁₂, the lamp heating is reduced to a state of L₂ (heating: 712).

Next, the lamp heating is switched at a time point (the time t₁₂) when it is detected that the temperature of the wafer 200 starts to be decreased, and thus, the temperature is increased to a level of L₃ (heating: 713) at the time point of a time t₁₃. By maintaining the level state of L₃ (heating: state 714) until a time t₁₄, the temperature 733 of the wafer 200 is maintained to be T12 close to the target value T₁₀, and one layer of the reaction layer on the surface of the wafer 200, which is formed by reacting with the excitation gas adsorbed to the surface, is removed.

At the time t₁₄, the heating by the lamp 151 is stopped, and the level of the lamp heating is set to L₀. At the time t₁₄, the flow rate of the cooling gas supplied from the gas supply pipe 111 to the back surface of the wafer 200 is changed to increase the pressure of the cooling gas on the back surface of the wafer 200. Accordingly, the heat exchange is efficiently performed between the sample stage 110 cooled by the coolant flowing through the flow passage 112 and the wafer 200, so that the wafer 200 can be cooled down to a temperature T11 suitable for adsorbing to the excitation gas surface in a relatively short time.

FIGS. 8A and 8B illustrate an example in a case of using a wafer having a large volume resistivity of the wafer as compared with the case of FIGS. 7A and 7B. In this manner, in a case where the lamp heating is controlled like the case of FIGS. 7A and 7B for a wafer having a large volume resistivity as compared with the case of FIGS. 7A and 7B, the wafer temperature is low at the time t₁₁ as illustrated by a dotted line in FIGS. 8A and 8B as compared with the target value T₁₀, at this time point, in a case where the lamp heating is switched from L₁ to be decreased to L₂ at the time t₁₂ and, then, is increased to L₃₁ (corresponding to L₃ in FIG. 7A) until the time t₁₃, the temperature of the wafer 200 remains at T₂₃ lower than the target value T₁₀. As a result, the reaction layer formed by reacting with the excitation gas adsorbed to the surface of the wafer 200 cannot be sufficiently detached from the surface of the wafer 200, and a portion thereof remains attached to the surface of the wafer 200, so that it is not possible to reliably remove the wafer surface layer.

On the contrary, in a case of using the method of the embodiment, by first checking the relationship between the temperature detected by the temperature sensor 115 and the temperature of the surface of the wafer similarly to the case of the example illustrated in FIGS. 7A and 7B, lamp heating control different from the case illustrated in FIGS. 7A and 7B as illustrated by the solid line in FIGS. 8A and 8B can be performed based on the temperature detected by the temperature sensor 115, and one layer of the reaction layer on the surface of the wafer 200, which is formed by reacting with the excitation gas adsorbed to the surface can be reliably removed.

That is, with respect to the wafer having a large volume resistivity in the case of FIGS. 8A and 8B as compared with the case of FIGS. 7A and 7B, the temperature rise characteristics of the surface are obtained by the above-mentioned method, by starting application of the power from the lamp power supply 150 to the lamp 151 at the time t₁₀, the lamp heating is set from the state L₀ to the state L₁ state (heating: state 811), and the temperature 831 of the wafer 200 is increased. This state of heating 811 is maintained, the lamp heating is switched from L₁ at a time point (a time t₂₁) when the wafer temperature 832 estimated from the temperature detected by the temperature sensor 115 reaches the preset target value T₁₀, and the lamp heating is reduced to a state of L₂₁ (heating: 812) at a time t₂₂. Next, the lamp heating is switched at a time point (a time t₂₂) when it is detected that the wafer temperature starts to be decreased, and the wafer temperature is increased to the level of L₃₁ at a time t₂₃ (heating: 813). By maintaining the level state of L₃₁ (heating: 814) until the time t₁₄ like the case of FIGS. 7A and 7B, the temperature 833 of the wafer 200 is maintained to be T₂₂ close to the target value T₁₀, and one layer of the reaction layer on the surface of the wafer 200, which is formed by reacting with the excitation gas adsorbed to the surface, is removed.

At a time t₂₄, the heating by the lamp 151 is stopped, and the lamp heating level is set to L₀. At the time t₂₄, the flow rate of the cooling gas supplied from the gas supply pipe 111 to the back surface of the wafer 200 is changed to increase the pressure of the gas on the back surface of the wafer 200. Accordingly, the heat exchange is efficiently performed between the sample stage 110 cooled by the coolant flowing through the flow passage 112 and the wafer 200, so that the wafer 200 can be cooled down to a temperature T₂₁ (corresponding to the temperature T₁₁ in FIGS. 7A and 7B) suitable for adsorbing to the excitation gas surface in a relatively short time.

In this manner, by checking the relationship between the temperature detected by the temperature sensor 115 in advance and the temperature of the surface of the wafer for the wafer as the processing object, the removing of only the one reaction layer on the surface of the wafer 200 formed by reacting with the excitation gas within a predetermined period of time can be reliably performed while the temperature control of the wafer under heating conditions suitable for each wafer is performed. In addition, the time required for cooling the wafer 200 after removing the reaction layer can be shortened, and the processing can be reliably performed without lowering the throughput.

Herein, as a method of checking the relationship between the temperature detected by the temperature sensor 115 in advance and the temperature of the surface of the wafer for the wafer as the processing object, there is considered a method of performing checking at the first cycle of the repeatedly executed processing cycle, a method of heating the wafer in a fixed sequence before starting the repeatedly executed processing cycle and identifying the temperature rising rate of the wafer as the processing object from the temperature detected by the temperature sensor 115, or a method of heating the wafer by using a dummy wafer of the same specification and estimating the temperature rising rate of the wafer as the processing object from the temperature detected by the temperature sensor 115.

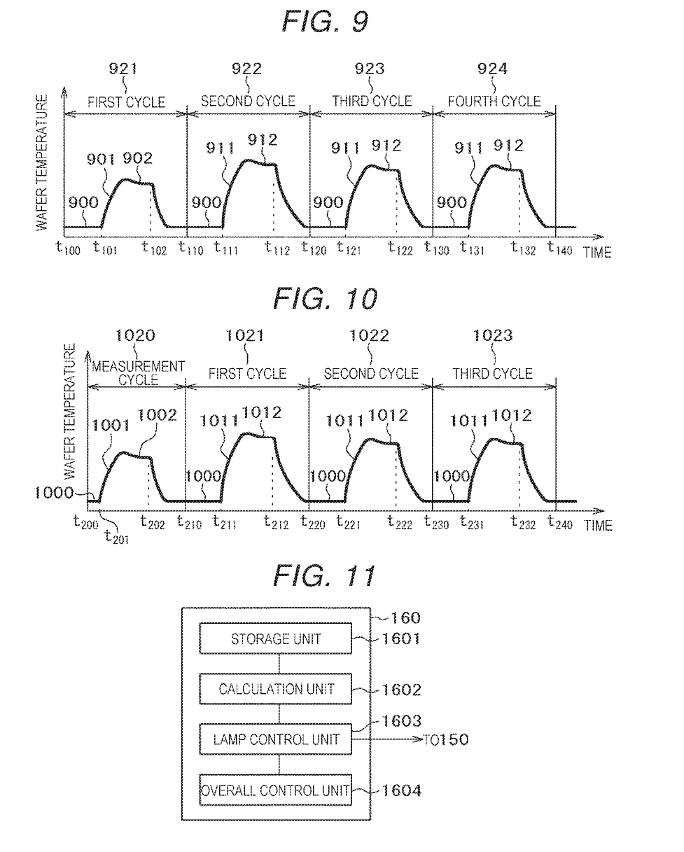

Among these methods, a method performed in the first cycle of the first repeatedly executed processing cycles will be described with reference to FIG. 9.

In the method illustrated in FIG. 9, in the preparation step of starting the first cycle 921 of the processing cycle, first, the power is applied from a power supply (not illustrated) to the pair of thin film electrodes 119 of the electrostatic chuck 117, so that wafer 200 Is adsorbed to the thin film electrode 119 by an electrostatic force. Next, by supplying the cooling gas from the gas supply pipe 111 to the back surface of the wafer 200, the wafer temperature is set to a temperature 900 suitable for adsorbing the excitation gas to the surface of the wafer 200. In this state, the process enters the first cycle 921. In the first cycle 921, a predetermined pattern is adopted as the pattern of the power applied from the lamp power supply 150 to the lamp 151.

That is, in the first cycle 921 of the process, the excitation gas excited by the plasma generated by the plasma generation chamber 102 and flowing out to the side of the processing chamber 103 at a time t₁₀₀ is adsorbed to the surface of the wafer for a predetermined period of time. After the excitation gas is adsorbed to the surface of the wafer for a predetermined period of time, the supply amount (flow rate) of the cooling gas from the gas supply pipe 111 to the back surface of the wafer 200 is adjusted to a flow rate suitable for heating at a time t₁₀₁, and by applying the power with a preset pattern from the lamp power supply 150 to the lamp 151, the wafer 200 is heated.

The temperature of the wafer 200 heated by the lamp 151 is increased like the curve 901 illustrated in FIG. 9, and by switching the power applied to the lamp 151 with a preset pattern, the temperature of the wafer 200 is maintained substantially constant like the curve 902. Herein, at the step where the temperature of the wafer 200 is being increased like the curve 901, the temperature rising rate (corresponding to A in FIG. 6) is obtained from the change in the temperature of the back surface of the wafer on the sample stage 110 detected by the temperature sensor 115, and the temperature rising rate (corresponding to E in FIG. 6) of the wafer 200 is obtained from the information of the temperature rising rate of the back surface of the wafer on the sample stage 110 by the method described with reference to FIG. 6 by using the database stored in the storage unit 1601 of the control unit 160. Next, based on the obtained data of the temperature rising rate of the wafer 200, the pattern of the power applied to the lamp 151 from the preset lamp power supply 150 is corrected.

The second cycle 922 and the subsequent cycles of the wafer processing are executed by using this corrected pattern. Accordingly, with respect to the temperature history of the wafer 200 in the heating process starting from a time t₁₁₁ (a time t₁₂₁ of the third cycle 923 and a time t₁₃₁ of the fourth cycle 924), the temperature is increased as indicated by the curve 911, and then, by switching the power applied to the lamp 151, the temperature is maintained to be a constant temperature (a temperature close to the target value T₁₀ described in FIGS. 7A, 7B, 8A, and 8B) until a time t₁₁₂ (a time t₁₂₂ of the third cycle 923 and a time t₁₃₂ of the fourth cycle 924) as indicated by the curve 912.

At the same time as the power applied to the lamp 151 is disconnected at the time t₁₁₂ (the time t₁₂₁ and the time t₁₃₁), the flow rate of the cooling gas supplied from the gas supply pipe 111 to the back surface of the wafer 200 is adjusted to a flow rate suitable for cooling the wafer 200, The wafer temperature is cooled down to a temperature of 900 suitable for adsorbing the excitation gas to the surface of the wafer. By executing the next wafer processing cycle (922 and the subsequent cycles) a predetermined number of times in a state where the wafer 200 is reliably cooled (a time t₁₂₀, a time t₁₃₀, and a time t₁₄₀), it is possible to reliably remove the layer formed on the surface of the wafer 200.

In this method, since the temperature rising rate of the wafer 200 is obtained in the wafer processing cycle, the surface layer can be reliably removed without lowering the throughput of the wafer processing.

On the other hand, since the heating pattern of the wafer 200 in the first cycle 921 is different from the heating pattern of the wafer 200 in the subsequent cycles, the removal of the surface layer of the wafer 200 in the first cycle 921 is not reliably performed, and thus, there is a possibility that a portion of the surface layer remains. However, by repeating the subsequent corrected removal cycle, the residue of the removal of the surface layer of the wafer 200 in the first cycle 921 becomes negligible.

Next, a method of identifying the temperature rising rate of the wafer as the processing object from the temperature detected by the temperature sensor 115 by heating the wafer in a fixed sequence before starting the repeated processing cycle will be described with reference to FIG. 10.

The difference from the method described in FIG. 9 is that a measurement cycle 1020 is provided instead of the first cycle 921 in FIG. 9. That is, in the first cycle 921 described in FIG. 9, the surface layer is removed by heating the wafer 200 in a state where the excitation gas is attached to the surface of the wafer 200. However, in the method illustrated in FIG. 10, the temperature rise characteristics of the wafer 200 are obtained by heating the wafer 200 in a state where the excitation gas is not attached to the surface of the wafer 200.

That is, in the method illustrated in FIG. 10, by applying the power from a power supply (not illustrated) to the pair of thin film electrodes 119 of the electrostatic chuck 117, the wafer 200 is adsorbed to the electrostatic chuck 117 by an electrostatic force. Next, by supplying the cooling gas from the gas supply pipe 111 to the back surface of the wafer 200, the wafer temperature is set to the temperature 1000 suitable for adsorbing the excitation gas to the surface of the wafer. In this state, measurement cycle 1020 is entered. In this measurement cycle 1020, as a pattern of the power to be applied from the lamp power supply 150 to the lamp 151, a preset pattern (for example, a pattern as illustrated in FIG. 7A) is adopted.

That is, in the measurement cycle 1020, in a state where the flow rate of the cooling gas supplied from the gas supply pipe 111 to the back surface of the wafer 200 at a time t₂₀₁ is adjusted such that the pressure of the back surface of the wafer 200 becomes a pressure suitable for heating the wafer 200, the power is applied from the lamp power supply 150 to the lamp 151 with a preset pattern to heat the wafer 200.

The temperature of the wafer 200 heated by the lamp 151 is increased like the curve 1001 illustrated in FIG. 10, and by switching the power applied to the lamp 151 with a preset pattern, the temperature of the wafer 200 is maintained substantially constant like the curve 1002. Herein, at the step where the temperature of the wafer 200 is being increased like the curve 1001, the temperature rising rate (corresponding to A in FIG. 6) is obtained from the change in the temperature of the back surface of the wafer on the sample stage 110 detected by the temperature sensor 115, and the temperature rising rate (corresponding to E in FIG. 6) of the wafer 200 is obtained from the information of the temperature rising rate of the back surface of the wafer in the sample stage 110 by the method described with reference to FIG. 6 by using the database stored in the storage unit 1601 of the control unit 160. Next, by using the obtained data of the temperature rising rate of the wafer 200, the pattern of the power applied to the lamp 151 from the preset lamp power supply 150 is corrected.

The first cycle 1021 and the subsequent cycles of the wafer processing are executed by using this corrected pattern. Accordingly, with respect to the temperature history of the wafer 200 in the heating process starting from a time t₂₁₁ (a time t₂₂₁ of the second cycle 1022 and a time t₂₃₁ of the third cycle 1023), the temperature is increased as indicated by the curve 1011, and then, by switching the power applied to the lamp 151, the temperature is maintained to be a constant temperature (target value T₁₀ described in FIGS. 7A, 7B, 8A, and 8B or a temperature close to the target value) until a time t₂₁₂ (a time t₂₂₂ of the second cycle 1022 and a time t₂₃₂ of the third cycle 1023) as indicated by the curve 1012.

At the same time as the power applied to the lamp 151 is disconnected at the time t₂₁₂, the flow rate of the cooling gas supplied from the gas supply pipe 111 is adjusted such that the pressure on the back surface of the wafer 200 becomes a pressure suitable for cooling the wafer 200, and thus, the wafer temperature is cooled down to a temperature (1000° C.) suitable for adsorbing the excitation gas to the surface of the wafer by the cooling gas. By executing the next wafer processing cycle (1022 and the subsequent cycles) a predetermined number of times in a state where the wafer 200 is reliably cooled (at a time t₂₂₀), it is possible to reliably remove the layer formed on the surface of the wafer 200.

According to this method, since the temperature rise characteristics of the wafer 200 are obtained without the process of removing the surface layer of the wafer, it is possible to reliably remove the layers one by one in the process of removing the surface layer of the wafer, and the wafer surface treatment, and it is possible to reliably execute the process with a high quality without generating residues of the removal.

The method of estimating the temperature rising rate of the wafer as the processing object from the temperature detected by the temperature sensor 115 by heating the wafer by using a dummy wafer of the same specification is the same as a combination of the method described with reference to FIG. 5 to FIGS. 8A and 8B and the second cycle 922 and the subsequent cycles described with reference to FIG. 9 or the first cycle 1021 and the subsequent cycles described with reference to FIG. 10, and thus, the description is omitted.

In FIG. 11, a schematic configuration of the control unit 160 for controlling the plasma processing apparatus 100 according to the embodiment will be described with reference to FIG. 11.

The control unit 160 for controlling the plasma processing apparatus 100 according to the embodiment includes a storage unit 1601, a calculation unit 1602, a lamp control unit 1603, and an overall control unit 1604.

The storage unit 1601 stores a program for controlling the entire plasma processing apparatus 100 including the vacuum exhaust device 120, the high frequency power supply 130, the gas supply source 140, the lamp power supply 150, the gas flow rate control unit 161, the coolant temperature controller 162, and the sensor controller 163, or the relationship between the PT sensor temperature and the TC wafer temperature as a database for volume resistivity, IR power, and He pressure as described with reference to FIG. 5.

The calculation unit 1602 obtains the temperature rising rate of the wafer 200 from the change in the temperature of the sample stage 110 detected by the temperature sensor 115 during the heating by the lamp 151 and the relationship between the PT sensor temperature and the TC wafer temperature for each of the volume resistivity, the IR power, and the He pressure stored in the storage unit 1601 by the method as explained in FIG. 6 by using the database stored in the storage unit 1601. The obtained result is reflected on the program for controlling the lamp power supply 150 stored in the storage unit 1601.

The lamp control unit 1603 controls the lamp power supply 150 for each wafer 200 of the processing object based on the control signal output from the control unit 160 based on the information of the temperature rising rate of the wafer 200 obtained by the calculation unit 1602.

The overall control unit 1604 controls the entire plasma processing apparatus 100 including the vacuum exhaust device 120, the high frequency power supply 130, the gas supply source 140, the lamp power supply 150, the gas flow rate control unit 161, the coolant temperature controller 162, and the sensor controller 163 based on the control program stored in the storage unit 1601.

As described above, according to the embodiments, and according to the present invention, even for a wafer of which temperature rising rate (volume resistivity) is unknown, it is possible to maintain the minimum temperature required for the process for a predetermined period of time without lowering the throughput of the processing, and it is possible to improve the yield of the processing.

Heretofore, although the invention made by the present inventor has been specifically described based on the embodiments, the invention is not limited to the above-mentioned embodiments, and various modifications can be made without departing from the spirit of the invention. For example, the above embodiments have been described in detail in order to explain the invention in an easy-to-understand manner, and the embodiments are not necessarily limited to those having all the configurations described. In addition, it is possible to perform addition, deletion, and replacement of another configuration with respect to a portion of the configuration of each embodiment.

1. A plasma processing apparatus comprising:
a vacuum container;
a sample stage on which a sample is mounted in an interior of the vacuum container;
an exhaust unit which exhausts the interior of the vacuum container;
a gas supply unit which supplies a processing gas to the interior of the vacuum container;
a high frequency power application unit which applies a high frequency power to the interior of the vacuum container;
an irradiation unit which irradiates the sample mounted on the sample stage with infrared light from an outside of the vacuum container;
a control unit which controls the exhaust unit, the gas supply unit, the high frequency power application unit, and the irradiation unit; and
a temperature measurement unit which measures a temperature of a surface of the sample stage on which the sample is mounted, wherein
the control unit controls an intensity of the infrared light with which the irradiation unit irradiates the sample based on the temperature measured by the temperature measurement unit when the irradiation unit irradiates the sample mounted on the sample stage with the infrared light.

2. The plasma processing apparatus according to claim 1, wherein
the sample stage includes a cooling gas supply unit which supplies a cooling gas between the sample stage and the back surface of the sample mounted on the sample stage, a coolant supply unit which supplies a coolant cooling the sample stage to a flow passage formed in the sample stage, and an electrostatic chuck unit which electrostatically adsorbs the sample mounted on the sample stage.

3. The plasma processing apparatus according to claim 1, wherein
the vacuum container includes: a plasma generation chamber which generates a plasma of the processing gas supplied from the gas supply unit by a high frequency power applied by the high frequency power application unit; and a processing chamber which introduces an excitation gas by the processing gas excited by the plasma generated in the plasma generation chamber, wherein a quartz plate having a large number of slits formed therein separates the plasma generation chamber and the processing chamber Plasma processing apparatus.

4. The plasma processing apparatus according to claim 1, wherein
when the irradiation unit irradiates the sample mounted on the sample stage with the infrared light, the control unit controls the intensity of the infrared light with which the irradiation unit irradiates the sample from a relationship between a volume resistivity and a temperature rising rate of the sample obtained in advance based on the temperature measured by the temperature measurement unit.

5. The plasma processing apparatus according to claim 4, wherein
the control unit obtains the temperature rising rate of the sample based on the temperature measured by the temperature measurement unit from the relationship between the volume resistivity and the temperature rising rate of the sample obtained in advance and controls the intensity of the infrared light with which the irradiation unit irradiates the sample based on the obtained temperature rising rate of the sample.

6. The plasma processing apparatus according to claim 5, wherein
the control unit performs the process of obtaining the temperature rising rate of the sample based on the temperature measured by the temperature measurement unit from the relationship between the volume resistivity and the temperature rising rate of the sample obtained in advance based on a temperature measured by the temperature measurement unit in a process of removing a first layer on the surface of the sample.

7. The plasma processing apparatus according to claim 5, wherein
the control unit performs the process of obtaining the temperature rising rate of the sample based on the temperature measured by the temperature measurement unit from the relationship between the volume resistivity and the temperature rising rate of the sample obtained in advance based on a temperature measured by the temperature measurement unit after heating the sample by irradiating the sample with the infrared light from the irradiation unit before removing a first layer on the surface of the sample.

8. A plasma processing method, which performs a process for removing layers on a surface of a sample one by one by repeating:
generating a plasma in an interior of a plasma generation chamber by applying a high frequency power from a high frequency power application unit to the interior of the plasma generation chamber in a state where a processing gas is supplied from a gas supply unit;
attaching an excitation gas due to the processing gas flowing into a processing chamber connected to the plasma generation chamber among the processing gas excited by plasma generated in the interior of the plasma generation chamber to a surface of a sample mounted on a sample stage in the interior of the processing chamber and cooled to a predetermined temperature; and
removing one layer of the surface of the sample by repeatedly irradiating the sample to which the excitation gas is attached with infrared light from an irradiation unit to heat the sample, wherein
the irradiation of the sample to which the excitation gas is attached with the infrared light from the irradiation unit is performed based on a temperature measured by a temperature measurement unit which measures a temperature of a surface of the sample stage on which the sample is mounted while controlling an intensity of the infrared light with which the irradiation unit irradiates the sample.

9. The plasma processing method according to claim 8, wherein
the attaching of the excitation gas to the surface of the sample mounted on the sample stage in the interior of the processing chamber and cooled to the predetermined temperature is performed while supplying a cooling gas from a cooling gas supply unit between a back surface of the sample mounted on the sample stage and the sample stage, supplying a coolant cooling the sample stage from a coolant supply unit to a flow passage formed in the sample stage, and electrostatically adsorbing the sample mounted on the sample stage to an electrostatic chuck unit.

10. The plasma processing method according to claim 8, wherein
the excitation gas passing through a quartz plate having a large number of slits formed therein and separating between the plasma generation chamber and the processing chamber, among the excitation gas due to the processing gas excited by the plasma generated in the interior of the plasma generation chamber, is attached to the surface of the sample which is mounted on the sample stage in the interior of the processing chamber and cooled to a predetermined temperature.

11. The plasma processing method according to claim 8, wherein
when the irradiation unit irradiates the sample mounted on the sample stage with the infrared light, the control unit controls the intensity of the infrared light with which the irradiation unit irradiates the sample from a relationship between a volume resistivity and a temperature rising rate of the sample obtained in advance based on the temperature measured by the temperature measurement unit.

12. The plasma processing method according to claim 11, wherein
the control unit obtains the temperature rising rate of the sample based on the temperature measured by the temperature measurement unit from the relationship between the volume resistivity and the temperature rising rate of the sample obtained in advance and controls the intensity of the infrared light with which the irradiation unit irradiates the sample based on the obtained temperature rising rate of the sample.

13. The plasma processing method according to claim 12, wherein
the process of obtaining, in the control unit, the temperature rising rate of the sample based on the temperature measured by the temperature measurement unit from the relationship between the volume resistivity and the temperature rising rate of the sample obtained in advance is performed based on a temperature measured by the temperature measurement unit in a process of removing a first layer on the surface of the sample.

14. The plasma processing method according to claim 12, wherein
the process of obtaining, in the control unit, the temperature rising rate of the sample based on the temperature measured by the temperature measurement unit from the relationship between the volume resistivity and the temperature rising rate of the sample obtained in advance is performed based on a temperature measured by the temperature measurement unit after heating the sample by irradiating the sample with the infrared light from the irradiation unit before removing a first layer on the surface of the sample.
